(19) United States
(12) Patent Application Publication
(10) Pub. No.: US 2025/0063874 A1
(43) Pub. Date: Feb. 20, 2025

(54) Display Device

(71) Applicant: LG Display Co., Ltd., Seoul (KR)

(72) Inventor: Joonyoung Kwon, Gumi-si (KR)

(21) Appl. No.: 18/773,380

(22) Filed: Jul. 15, 2024

(30) Foreign Application Priority Data
Aug. 18, 2023 (KR) 10-2023-0108180

(51) Int. Cl. H01L 33/62; G06F 3/044; H01L 25/16; H01L 27/12

(52) U.S. Cl. CPC H01L 33/62; G06F 3/0443; H01L 25/167; H01L 27/1255; G06F 2203/04111

(57) ABSTRACT

A display device presented herein includes a substrate including a display area with a plurality of subpixels, and a non-display area surrounding the display area, a plurality of transistors in the plurality of subpixels, a planarization layer covering the plurality of transistors, a light-emitting element on the planarization layer, a plurality of first pad electrodes in the non-display area, and an organic film on the plurality of first pad electrodes, in which the planarization layer covers edges of the plurality of first pad electrodes and is spaced apart from the organic film. The reliability of the display device presented herein is improved by suppressing arcing caused by damage to the pad electrode.

### CROSS-REFERENCE TO RELATED APPLICATION

This application claims the priority from Republic of Korea Patent Application No. 10-2023-0108180 filed on Aug. 18, 2023, which is hereby incorporated by reference in its entirety.

### BACKGROUND

### Field

The present disclosure relates to a display device, and more particularly, to a display device in which damage to a pad electrode is minimized or at least reduced.

### Description of Related Art

Recently, display devices, which visually display electrical information signals, are being rapidly developed in accordance with the full-fledged entry into the information era. Various studies are being continuously conducted to develop a variety of display devices which are thin and lightweight, consume low power, and have improved performance.

Among the various display devices, a light-emitting display device refers to a display device that autonomously emits light. Unlike a liquid crystal display device, the light-emitting display device does not require a separate light source and thus may be manufactured as a lightweight, thin display device. In addition, the light-emitting display device is advantageous in terms of power consumption because the light-emitting display device operates at a low voltage. Further, the light-emitting display device is expected to be adopted in various fields because the light-emitting display device is also excellent in implementation of colors, response speeds, viewing angles, and contrast ratios (CRs).

### SUMMARY

An object to be achieved by the present disclosure is to provide a display device in which damage to a pad electrode is minimized or at least reduced.

Another object to be achieved by the present disclosure is to provide a display device in which the occurrence of static electricity on a pad electrode is minimized or at least reduced.

Still another object to be achieved by the present disclosure is to provide a display device capable of suppressing arcing and improving reliability.

Objects of the present disclosure are not limited to the above-mentioned objects, and other objects, which are not mentioned above, can be clearly understood by those skilled in the art from the following descriptions.

In one or more embodiments of the present disclosure, there is provided a display device including: a substrate including a display area with a plurality of subpixels, and a non-display area surrounding the display area, a plurality of transistors in the plurality of subpixels, a planarization layer covering the plurality of transistors, a light-emitting element on the planarization layer, a plurality of first pad electrodes in the non-display area, and an organic film on the plurality of first pad electrodes, in which the planarization layer covers edges of the plurality of first pad electrodes and is spaced apart from the organic film. Therefore, it is possible to improve the reliability of the display device by suppressing arcing caused by damage to the pad electrode.

Other detailed matters of the embodiments of the present disclosure are included in the detailed description and the drawings.

The present disclosure may minimize or at least reduce damage to the pad electrode.

The present disclosure may minimize or at least reduce the occurrence of static electricity on the pad electrode.

The present disclosure may improve reliability of the display device by suppressing arcing.

The effects according to the present disclosure are not limited to the contents exemplified above, and more various effects are included in the present disclosure.

### BRIEF DESCRIPTION OF DRAWINGS

The above and other embodiments, features and other advantages of the present disclosure will be more clearly understood from the following detailed description taken in conjunction with the accompanying drawings, in which:

FIG. 1 is a schematic top plan view of a display device according to one or more embodiments of the present disclosure;

FIG. 2 is an enlarged top plan view of area A in FIG. 1 according to one or more embodiments of the present disclosure;

FIG. 3 is a cross-sectional view taken along line III-III′ in FIG. 1 according to one or more embodiments of the present disclosure;

FIG. 4 is a cross-sectional view taken along line IV-IV′ in FIG. 2 according to one or more embodiments of the present disclosure;

FIG. 5 is a cross-sectional view taken along line V-V′ in FIG. 2 according to one or more embodiments of the present disclosure; and

FIG. 6 is a cross-sectional view of a display device according to one or more embodiments of the present disclosure.

### DETAILED DESCRIPTION

Advantages and characteristics of the present disclosure and a method of achieving the advantages and characteristics will be clear by referring to embodiments described below in detail together with the accompanying drawings. However, the present disclosure is not limited to the embodiments disclosed herein but will be implemented in various forms. The embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to embodiments of the present disclosure will be described in detail with reference to accompanying drawings.

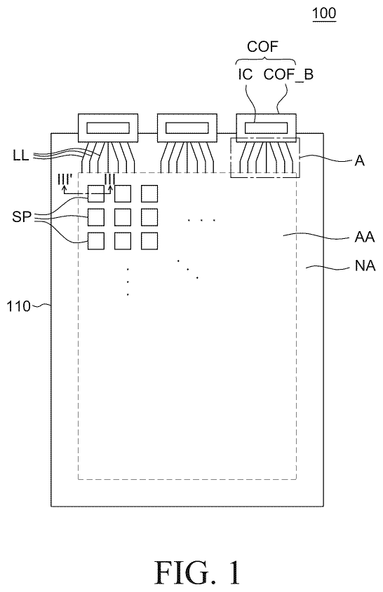

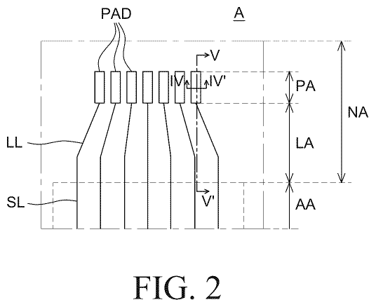

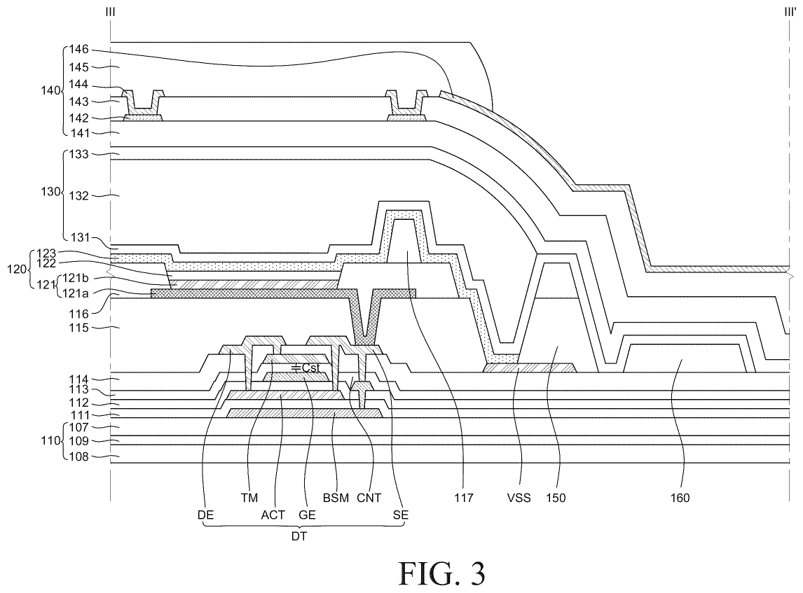

FIG. 1 is a schematic top plan view of a display device according to one or more embodiments of the present disclosure. FIG. 2 is an enlarged top plan view of area A in FIG. 1 according to one or more embodiments of the present disclosure. FIG. 3 is a cross-sectional view taken along line III-III′ in FIG. 1 according to one or more embodiments of the present disclosure. FIG. 1 illustrates only a substrate 110, link lines LL, and flexible films COF among various constituent elements of a display device 100, and FIG. 2 does not illustrate the flexible film COF.

With reference to FIGS. 1 and 2, the display device 100 according to the one or more embodiments of the present disclosure may include the substrate 110, signal lines SL, the link lines LL, pad electrodes PAD, and the flexible films COF.

With reference to FIG. 3 together, the substrate 110 may include a first substrate 107, an interlayer insulation film 109, and a second substrate 108.

The first substrate 107 and the second substrate 108 may be substrates, i.e., insulation substrates configured to support constituent elements disposed above the substrate 110. For example, the first substrate 107 and the second substrate 108 may be made of glass, resin, or the like. In addition, the first substrate 107 and the second substrate 108 may include polymer or plastic. In several embodiments, the first substrate 107 and the second substrate 108 may be made of a plastic material having flexibility.

The interlayer insulation film 109 may be disposed between the first substrate 107 and the second substrate 108. The interlayer insulation film 109 may protect the first substrate 107 and the second substrate 108 from the penetration of moisture.

The plurality of pixels may be formed on the substrate 110 so that images may be displayed. The substrate 110 may include the display area AA and the non-display area NA configured to surround the display area AA.

The display area AA is an area of the display device 100 in which images are displayed. The display area AA may include a plurality of subpixels SP constituting a plurality of pixels, and the plurality of signal lines SL configured to operate the plurality of subpixels SP. The plurality of subpixels SP is minimum units that constitute the display area AA. The n subpixels SP may constitute a single pixel. A light-emitting element, a thin-film transistor for operating the light-emitting element, and the like may be disposed in each of the plurality of subpixels SP. The plurality of light emitting elements may be differently defined depending on the type of display panel. For example, the light-emitting element may be an organic light-emitting diode (OLED).

The plurality of signal lines SL may extend from the display area AA to the non-display area NA and be electrically connected to the pad electrode PAD. The plurality of signal lines SL may be respectively connected to the plurality of subpixels SP and transmit various types of signals. For example, the plurality of signal lines SL may be gate lines, data lines, power lines, or scan lines. However, the present disclosure is not limited thereto.

The non-display area NA may be defined as an area in which no image is displayed, i.e., an area extending from the display area AA. The non-display area NA may include a pad area PA, and a link area LA.

The link area LA may be disposed between the display area AA and the pad area PA. The link area LA is an area in which the link lines LL are disposed to transmit signals to the signal lines SL disposed in the display areas AA, and various link lines LL may be disposed in the link area LA. The plurality of link lines LL may be respectively connected to the plurality of pad electrodes PAD in the pad area PA. For example, the plurality of link lines LL may be gate link lines, data link lines, power link lines, or power supply lines. However, the present disclosure is not limited thereto. In addition, the plurality of link lines LL may be made of the same material as first and second metal layers to be described below. However, the present disclosure is not limited thereto.

The pad area PA is an area in which no image is displayed. The plurality of pad electrodes PAD may be disposed in the pad area PA. The pad area PA may be an area extending from one side of the link area LA. For example, the pad area PA may be an area in which a power supply pad electrode, a data pad electrode, a gate pad electrode, and the like are disposed.

In addition, the flexible film COF on which a driving chip IC for transmitting a signal to the subpixel SP in the display area AA is mounted may be disposed in the non-display area NA. The flexible film COF may include a base film COF_B, the driving chip IC, and a pad part.

The base film COF_B is a layer for supporting the flexible film COF. The base film COF_B may be made of an insulating material, e.g., an insulating material having flexibility.

The driving chip IC is a component configured to process data for displaying the image and process a driving signal for processing the data. The driving chip IC may be electrically connected to the substrate 110 through the pad part. The driving chip IC may be mounted in a chip-on-film (COF) manner. However, the present disclosure is not limited thereto.

Meanwhile, although not illustrated in the drawings, the pad part may supply a power voltage, a data voltage, and the like to the plurality of subpixels SP in the display area AA through the pad electrode PAD disposed in the pad area PA. The pad part may be made of an electrically conductive material such as copper (Cu). However, the present disclosure is not limited thereto.

With reference to FIG. 3, a light-blocking layer BSM may be disposed on the substrate 110. The light-blocking layer BSM may block light entering active layers ACT of a plurality of transistors, thereby minimizing or at least reducing a leakage current. For example, the light-blocking layer BSM may be disposed below an active layer ACT of a transistor DT and block light entering the active layer ACT. If the light is incident on the active layer ACT, a leakage current occurs, which may degrade the reliability of the transistor DT. Therefore, the light-blocking layer BSM for blocking light may be disposed on the substrate 110, thereby improving the reliability of the transistor DT. The light-blocking layer BSM may be made of an opaque electrically conductive material, for example, copper (Cu), aluminum (Al), molybdenum (Mo), nickel (Ni), titanium (Ti), chromium (Cr), or an alloy thereof. However, the present disclosure is not limited thereto.

A buffer layer 111 may be disposed on the light-blocking layer BSM. The buffer layer 111 may reduce the penetration of moisture or impurities through the substrate 110. For example, the buffer layer 111 may be configured as a single layer or multilayer made of silicon oxide (SiOx) or silicon nitride (SiNx). However, the present disclosure is not limited thereto. However, the buffer layer 111 may be excluded in accordance with the type of the substrate 110 or the type of transistor DT. However, the present disclosure is not limited thereto.

The transistor DT including the active layer ACT, a gate electrode GE, a source electrode SE, and a drain electrode DE may be disposed on the buffer layer 111.

Meanwhile, although not illustrated in FIG. 3, an additional buffer layer may be disposed between the substrate 110 and the light-blocking layer BSM. For example, like the buffer layer 111, the additional buffer layer may be configured as a single layer or multilayer made of silicon oxide (SiOx) or silicon nitride (SiNx) in order to reduce the penetration of moisture or impurities through the substrate 110. However, the present disclosure is not limited thereto.

First, the active layer ACT of the transistor DT may be disposed on the buffer layer 111. The active layer ACT may be made of a semiconductor material such as an oxide semiconductor, amorphous silicon, or polysilicon. However, the present disclosure is not limited thereto. In addition, although not illustrated in the drawings, in addition to the transistor DT, other transistors, such as a switching transistor, a sensing transistor, and a light emission control transistor, may be additionally disposed. The active layers of these transistors may be made of a semiconductor material such as an oxide semiconductor, amorphous silicon, or polysilicon. However, the present disclosure is not limited thereto. In addition, the active layers of the transistors, such as the transistor DT, the switching transistor, the sensing transistor, and the light emission control transistor, which are included in pixel circuits, may be made of the same material or different materials.

A gate insulation layer 112 may be disposed on the active layer ACT. The gate insulation layer 112 may be an insulation layer for electrically insulating the active layer ACT and the gate electrode GE. The gate insulation layer 112 may be configured as a single layer or multilayer made of silicon oxide (SiOx) or silicon nitride (SiNx). However, the present disclosure is not limited thereto.

The gate electrode GE may be disposed on the gate insulation layer 112. The gate electrode GE may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

In addition, a connection electrode CNT may be disposed on the gate insulation layer 112. The connection electrode CNT may be made of the same material as the gate electrode GE and electrically connected to the source electrode SE and the light-blocking layer BSM.

A first interlayer insulation layer 113 and a second interlayer insulation layer 114 may be disposed on the gate electrode GE. Contact holes, through which the source electrode SE and the drain electrode DE are connected to the active layer ACT, are formed in the first interlayer insulation layer 113 and the second interlayer insulation layer 114. The first interlayer insulation layer 113 and the second interlayer insulation layer 114 are insulation layers for protecting components disposed below the first interlayer insulation layer 113 and the second interlayer insulation layer 114. The first interlayer insulation layer 113 and the second interlayer insulation layer 114 may each be configured as a single layer or multilayer made of silicon oxide (SiOx) or silicon nitride (SiNx). However, the present disclosure is not limited thereto.

A storage capacitor Cst may be disposed on the gate insulation layer 112. The storage capacitor Cst may be implemented by using an intermediate electrode TM and the gate electrode GE as capacitor electrodes. However, the present disclosure is not limited thereto. The storage capacitor Cst may be implemented in various ways.

The intermediate electrode TM may be disposed on the first interlayer insulation layer 113. The intermediate electrode TM may be disposed to overlap the gate electrode GE with the first interlayer insulation layer 113 interposed therebetween.

The source electrode SE and the drain electrode DE are disposed on the second interlayer insulation layer 114 and electrically connected to the active layer ACT. The drain electrode DE may be electrically connected to the storage capacitor Cst, and the source electrode SE may be connected to a first electrode 121 of a light-emitting element 120. The source electrode SE and the drain electrode DE may each be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

A planarization layer 115 may be disposed on the source electrode SE and the drain electrode DE. The planarization layer 115 may planarize an upper portion of the pixel circuit including the transistor DT. The planarization layer 115 may be configured as a single layer or multilayer and made of benzocyclobutene (BCB) or an acrylic-based organic material, for example. However, the present disclosure is not limited thereto.

The plurality of light-emitting elements 120 is provided on the planarization layer 115 and respectively disposed in the plurality of subpixels SP. The light-emitting elements 120 may be elements configured to emit light by the current and include a red light-emitting element configured to emit red light, a green light-emitting element configured to emit green light, and a blue light-emitting element configured to emit blue light. A combination of the light-emitting elements 120 may implement various colors including white. For example, the light-emitting element 120 may be an organic light-emitting diode (OLED). However, the present disclosure is not limited thereto.

The light-emitting element 120 may include the first electrode 121, a light-emitting layer 122, and a second electrode 123.

The first electrode 121 may be disposed on the planarization layer 115. The first electrode 121 may include a reflective layer 121a and a transparent conductive layer 121b. Specifically, the transparent conductive layer 121b may be disposed on the reflective layer 121a. The reflective layer 121a and the transparent conductive layer 121b are layers for supplying holes to the light-emitting layer 122. The reflective layer 121a and the transparent conductive layer 121b may each be made of an electrically conductive material having a high work function. For example, the reflective layer 121a may have a layered structure made of an alloy of silver (Ag), palladium (Pd), and copper (Cu) that are metallic materials with high reflectance. However, the present disclosure is not limited thereto. For example, the transparent conductive layer 121b may be made of indium-tin-oxide (ITO) that is transparent conductive oxide (TCO). However, the present disclosure is not limited thereto.

A bank 116 may be disposed on the reflective layer 121a and the planarization layer 115. The bank 116 may cover an edge of the reflective layer 121a of the light-emitting element 120 and define a light-emitting area. That is, the bank 116 may separate the plurality of subpixels SP. The bank 116 may be made of an insulating material to insulate the first electrodes 121 of the adjacent subpixels SP. In addition, the bank 116 may be configured as a black bank with a high optical absorption rate to suppress a color mixture between the adjacent subpixels SP. For example, the bank 116 may be made of polyimide resin, acrylic resin, or benzocyclobutene (BCB) resin. However, the present disclosure is not limited thereto.

A spacer 117 may be disposed on the bank 116. The spacer 117 refers to a layer that maintains a predetermined distance between a deposition mask and the bank 116 to suppress damage caused by contact with the deposition mask. Like the bank 116, the spacer 117 may be made of polyimide resin, acrylic resin, or benzocyclobutene (BCB) resin. However, the present disclosure is not limited thereto. The bank 116 and the spacer 117 are separately illustrated in FIG. 3. However, the bank 116 and the spacer 117 may be formed integrally and simultaneously by a single process.

The light-emitting layer 122 may be disposed on the first electrode 121. The light-emitting layer 122 is a layer that emits light by combining electrons and holes.

The second electrode 123 may be disposed on the light-emitting layer 122. The second electrode 123 may be made of a metallic material with a low work function in order to smoothly supply electrons to the light-emitting layer 122. For example, the second electrode 123 may be made of a metallic material selected from calcium (Ca), barium (Ba), aluminum (Al), silver (Ag), and an alloy containing one or more of the above-mentioned elements. However, the present disclosure is not limited thereto.

The light-emitting element 120 may further include a hole injection layer, a hole transport layer, an electron transport layer, an electron injection layer, and the like to improve luminous efficiency of the light-emitting element 120. For example, the hole injection layer and the hole transport layer may be disposed between the first electrode 121 and the light-emitting layer 122, and the electron transport layer and the electron injection layer may be disposed between the light-emitting layer 122 and the second electrode 123. In addition, a hole blocking layer or an electron blocking layer may be disposed on the light-emitting layer 122 to further improve the efficiency in recombining of holes and electrons.

An encapsulation layer 130 may be disposed on the light-emitting element 120. The encapsulation layer 130 may protect the light-emitting element 120 from external moisture, oxygen, impact, and the like. The encapsulation layer 130 may have a multilayer structure in which an inorganic layer, which is made of an inorganic insulating material, and an organic layer, which is made of an organic material, are stacked. For example, the encapsulation layer 130 may have a multilayer structure including at least one organic layer and at least two inorganic layers and made by alternately stacking the inorganic layers and the organic layer. However, the present disclosure is not limited thereto. For example, the encapsulation layer 130 may have a three-layer structure including a first inorganic encapsulation layer 131, an organic encapsulation layer 132, and a second inorganic encapsulation layer 133. In this case, the first inorganic encapsulation layer 131 and the second inorganic encapsulation layer 133 may each be made of one or more materials selected from a group consisting of silicon nitride (SiNx), silicon oxide (SiOx), aluminum oxide (AlOx), and silicon oxynitride (SiON). However, the present disclosure is not limited thereto. Meanwhile, the organic encapsulation layer 132 may be made of one or more materials selected from a group consisting of epoxy resin, polyimide resin, polyethylene resin, and silicon oxycarbide (SiOC). However, the present disclosure is not limited thereto.

A touch detection part 140 may be disposed on the encapsulation layer 130 to recognize a user's touch. The touch detection part 140 may include a touch buffer layer 141, a touch bridge electrode 142, a touch insulation layer 143, a touch electrode 144, a touch protective layer 145 and a touch line 146.

The touch buffer layer 141 may be disposed on the encapsulation layer 130. The touch buffer layer 141 may be a layer for suppressing damage to the light-emitting element 120 and the encapsulation layer 130 and made of an inorganic material excellent in barrier properties. Therefore, it is possible to minimize or at least reduce the penetration of moisture or oxygen. For example, the touch buffer layer 141 may be configured as a single layer or multilayer made of silicon nitride (SiNx) or silicon oxide (SiOx). However, the present disclosure is not limited thereto.

The touch bridge electrode 142 may be disposed on the touch buffer layer 141. The touch bridge electrode 142 may connect the touch electrode 144.

The touch insulation layer 143 may be disposed on the touch buffer layer 141 and the touch bridge electrode 142. The touch insulation layer 143 may be a layer for insulating the touch bridge electrode 142 and the touch electrode 144 and made of an inorganic material. For example, the touch insulation layer 143 may be configured as a single layer or multilayer made of silicon oxide (SiOx) or silicon nitride (SiNx). However, the present disclosure is not limited thereto.

The touch electrode 144 may be disposed on the touch insulation layer 143. The touch electrode 144 is an electrode configured to detect a touch input. The touch electrode 144 may include a sensing electrode and a driving electrode and detect touch coordinates by sensing a change in capacitance between the sensing electrode and the driving electrode. For example, the touch electrode 144 may be made of a transparent metallic material, such as indium-tin-oxide (ITO) or indium-zinc-oxide (IZO), that may transmit light. However, the present disclosure is not limited thereto.

In addition, a touch line 146 may be disposed on the touch insulation layer 143. The touch line 146 may electrically connect the touch electrode 144 and a touch circuit. The touch line 146 may be disposed on the same layer as the touch electrode 144. However, the present disclosure is not limited thereto.

The touch protective layer 145 may be disposed on the touch electrode 144. The touch protective layer 145 is a layer that suppresses a short circuit of or damage to the touch electrode 144 and planarizes a top surface of the touch electrode 144. For example, the touch protective layer 145 may be made of a transparent insulation resin such as acrylic resin, polyester resin, or epoxy resin. However, the present disclosure is not limited thereto.

Next, a common power line VSS connected to the second electrode 123 may be disposed in the non-display area NA. The common power line VSS may be electrically connected to the second electrode 123 of the light-emitting element 120 and apply a power voltage to the light-emitting element 120.

A dam 150 may be disposed on the common power line VSS. The dam 150 is disposed to prevent an overflow of the organic encapsulation layer 132 of the encapsulation layer 130. The dam 150 may include a lower layer made of the same material as the planarization layer 115, and an upper layer made of the same material as the bank 116. However, the present disclosure is not limited thereto. The dam 150 may include three or more layers. In addition, FIG. 3 illustrates only one dam 150. However, the present disclosure is not limited thereto. The encapsulation layer 130, the touch buffer layer 141, and the touch insulation layer 143 may be disposed above the dam 150.

The crack suppression layer 160 may be disposed outside the dam 150. The crack suppression layer 160 may mitigate an external impact and inhibit cracks from propagating to the display area AA. Therefore, the crack suppression layer 160 may be made of an organic insulating material with a high strain rate and impact resistance. For example, the crack suppression layer 160 may be made of the same material as the planarization layer 115 or the bank 116. However, the present disclosure is not limited thereto.

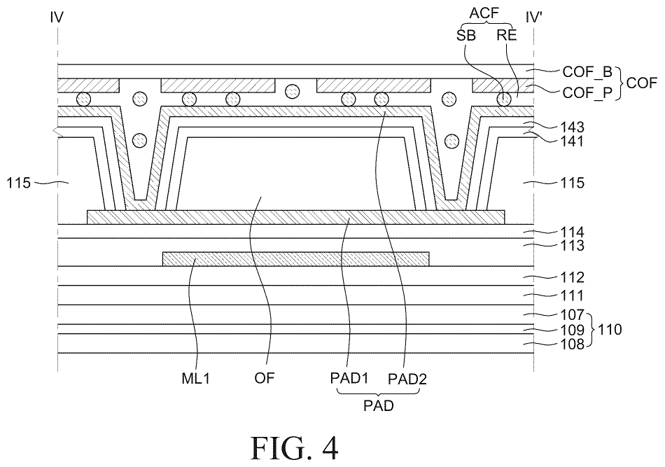

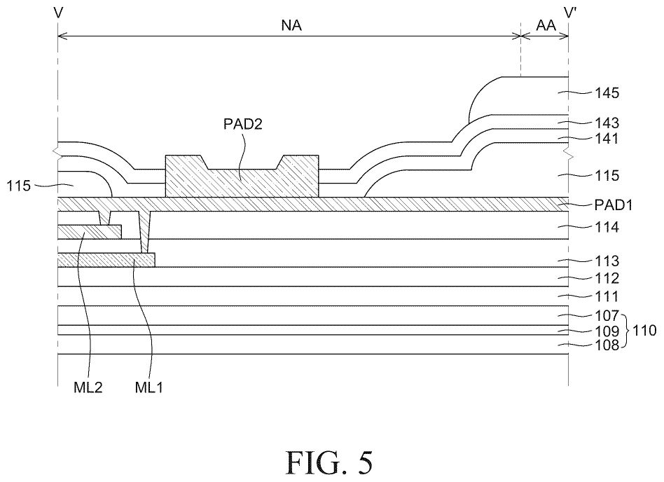

Hereinafter, the pad electrode PAD of the display device 100 according to one or more embodiments of the present disclosure will be described in detail with reference to FIGS. 4 to 5.

FIG. 4 is a cross-sectional view taken along line IV-IV′ in FIG. 2 according to one or more embodiments of the present disclosure. FIG. 5 is a cross-sectional view taken along line V-V′ in FIG. 2 according to one or more embodiments of the present disclosure. FIG. 4 is a view illustrating a state in which the flexible film COF is bonded. FIG. 5 is a cross-sectional view of a portion where an organic film OF is not disposed.

With reference to FIGS. 4 to 5 together, the buffer layer 111 and the gate insulation layer 112 may be disposed on the substrate 110.

Among a plurality of metal layers, a first metal layer ML1 may be disposed on the gate insulation layer 112. The first metal layer ML1 may be electrically connected to a first pad electrode PAD1 to transmit signals to the display area AA. The first metal layer ML1 may be made of the same material as the gate electrode GE of the transistor DT. However, the present disclosure is not limited thereto.

The first interlayer insulation layer 113 may be disposed on the first metal layer ML1.

With reference to FIG. 5, a second metal layer ML2, among the plurality of metal layers, may be disposed on the first interlayer insulation layer 113. Like the first metal layer ML1, the second metal layer ML2 may be electrically connected to the first pad electrode PAD1 to transmit signals to the display area AA. The second metal layer ML2 may be made of the same material as the intermediate electrode TM among the electrodes of the storage capacitor Cst. However, the present disclosure is not limited thereto.

Among the pad electrodes, the first pad electrode PAD1 may be disposed on the plurality of metal layers. The first pad electrode PAD1 may transmit signals to the plurality of subpixels SP or be electrically connected to a printed circuit board. In this case, an edge of the first pad electrode PAD1 may be covered by the planarization layer 115. Specifically, the first pad electrode PAD1 may be disposed on the same layer as the source electrode SE and the drain electrode DE of the transistor DT and made of the same material as the source electrode SE and the drain electrode DE.

The organic film OF may be disposed on the first pad electrode PAD1. The organic film OF may be spaced apart from the planarization layer 115 and protect a portion of the first pad electrode PAD1 that is exposed without being covered by the planarization layer 115. In this case, the organic film OF may be made of the same material as the planarization layer 115.

The touch buffer layer 141 and the touch insulation layer 143 may be disposed on the organic film OF to cover an organic film OF. In this case, the touch buffer layer 141 and the touch insulation layer 143 may be disposed to expose a part of the first pad electrode PAD1 to connect the first pad electrode PAD1 and a second pad electrode PAD2.

Among the pad electrodes, the second pad electrode PAD2 may be disposed on the organic film OF, the touch insulation layer 143 and the first pad electrode PAD1. In one or more embodiments, the touch buffer layer 141 and the touch insulation layer 143 may not be disposed in the non-display area NA. In such cases, the second pad electrode PAD2 may be disposed on the organic film OF and the first pad electrode PAD1. Like the first pad electrode PAD1, the second pad electrode PAD2 may transmit signals to the plurality of subpixels SP or be electrically connected to the printed circuit board. In such cases, the second pad electrode PAD2 may be connected to the first pad electrode PAD1 through contact holes of the touch buffer layer 141 and the touch insulation layer 143. The second pad electrode PAD2 may be made of the same material as one of the touch bridge electrode 142 and the touch electrode 144. However, the present disclosure is not limited thereto.

With reference to FIG. 4, the flexible film COF may be disposed on the second pad electrode PAD2, and a pad part COF_P of the flexible film COF may be electrically connected to the second pad electrode PAD2 through a conductive bonding layer ACF.

The conductive bonding layer ACF may be disposed on the plurality of second pad electrodes PAD2 to bond the plurality of second pad electrodes PAD2 and the flexible film COF. The conductive bonding layer ACF may be in a state in which conductive balls SB used for bonding and electrical connection are dispersed into resin RE.

In case that the light-emitting layer is an organic layer in the display device, the light-emitting layer may be formed by thermal vapor deposition using a mask. Specifically, in order to separately form the light-emitting layers respectively disposed in red subpixels, green subpixels, and blue subpixels, a fine metal mask (FMM) is used. In such cases, the display device may have a defect in which the pad electrode is dented by a sag of the fine metal mask.

In particular, in the case of the display device using a touch-on-encapsulation (ToE) method that disposes the touch detection part on the encapsulation layer, the dented pad electrode may be more problematic. The touch bridge electrode is formed by a deposition process, a photolithography process, and an etching process. In case that the etching process is performed in a state in which the pad electrode is dented by a sag of the mask, the touch insulation layer may be over-etched, and the pad electrode may be exposed. In this case, the exposed pad electrode may act as a lightning rod, and arcing may occur. In case that arcing occurs, the high current introduced into the pad electrode flows into the display device along the pad electrode, and static electricity occurs, which may cause a defect of the display device.

Therefore, in the display device 100 according to one or more embodiments of the present disclosure, the organic film OF is disposed on the portions of the plurality of first pad electrodes PAD1 that are exposed without being covered by the planarization layer 115. Therefore, even though the mask sags, the mask comes into contact with the organic film OF first, which may inhibit the first pad electrode PAD1 from being dented by the mask.

Therefore, in the display device 100 according to one or more embodiments of the present disclosure, the organic film OF is disposed on the plurality of first pad electrodes PAD1, and the exposure of the first pad electrode PAD1 is minimized or at least reduced, such that the inflow of electric current into the first pad electrode PAD1 caused by the sagged mask is suppressed, which may minimize or at least reduce static electricity, suppress arcing, and improve reliability.

That is, in the display device 100 according to one or more embodiments of the present disclosure, the organic film OF is disposed on the plurality of first pad electrodes PAD1, which may suppress damage to the first pad electrode PAD1.

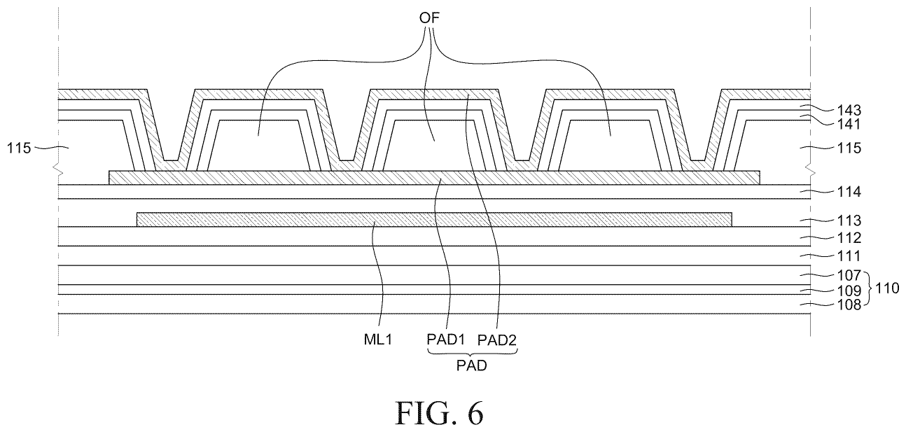

FIG. 6 is a cross-sectional view of a display device according to one or more embodiments of the present disclosure. The display device in FIG. 6 is substantially identical in configuration to the display device 100 in FIGS. 1 to 5, except for the organic film OF. Therefore, repeated descriptions of the identical components will be omitted.

With reference to FIG. 6, the organic film OF having a slit pattern may be disposed on the first pad electrode PAD1. That is, the organic film OF may include a plurality of organic patterns. The plurality of organic patterns may be disposed on the first pad electrode PAD1 and spaced apart from one another at predetermined intervals to protect the portion that is exposed without being covered by the planarization layer 115. The plurality of organic patterns may be disposed to be spaced apart from the planarization layer 115 and made of the same material as the planarization layer 115.

In such cases, the plurality of organic patterns is disposed on the first pad electrode PAD1 and spaced apart from one another, and the second pad electrode PAD2 is disposed on the plurality of organic patterns, such that the second pad electrode PAD2 may be electrically connected to the first pad electrode PAD1 exposed by the plurality of organic patterns.

Therefore, in the display device 100 according to one or more embodiments of the present disclosure, the organic film OF is disposed on the portions of the plurality of first pad electrodes PAD1 that are exposed without being covered by the planarization layer 115. Therefore, even though the mask sags, the mask comes into contact with the organic film OF first, which may inhibit the first pad electrode PAD1 from being dented by the mask. In such cases, the plurality of organic patterns may be disposed to be spaced apart from the planarization layer 115 and made of the same material as the planarization layer 115.

Therefore, in the display device 100 according to one or more embodiments of the present disclosure, a plurality of organic films OF are disposed on the first pad electrodes PAD1, and the exposure of the first pad electrode PAD1 is minimized or at least reduced, such that the inflow of electric current into the first pad electrode PAD1 caused by the sagged mask is suppressed, which may minimize or at least reduce static electricity, suppress arcing, and improve reliability.

That is, in the display device 100 according to one or more embodiments of the present disclosure, the organic film OF is disposed on the plurality of first pad electrodes PAD1, which may suppress damage to the first pad electrode PAD1.

The embodiments of the present disclosure can also be described as follows:

According to one or more embodiments of the present disclosure, there is provided a display device. The display device includes a substrate comprising a display area in which a plurality of subpixels is disposed, and a non-display area configured to surround the display area, a plurality of transistors respectively disposed in the plurality of subpixels, a planarization layer configured to cover the plurality of transistors, a light-emitting element disposed on the planarization layer, a plurality of first pad electrodes disposed in the non-display area, an organic film disposed on the plurality of first pad electrodes. The planarization layer covers edges of the plurality of first pad electrodes and is spaced apart from the organic film.

The organic film may comprise a plurality of organic patterns spaced apart from one another.

The organic film may be made of the same material as the planarization layer.

The display device may further include a plurality of second pad electrodes disposed on the plurality of first pad electrodes and the organic film and configured to adjoin the plurality of first pad electrodes.

The display device may further include a touch detection part disposed on the light-emitting element in the display area. The touch detection part may further comprise an insulation layer, a plurality of touch electrodes, and a plurality of touch bridge electrodes. The plurality of second pad electrodes may be made of the same material as one of the plurality of touch electrodes and the plurality of touch bridge electrodes.

The insulation layer may be disposed on the plurality of first pad electrodes and covers the organic film. The plurality of second pad electrodes may be connected to the plurality of first pad electrodes through a contact hole of the insulation layer.

The display device may further include a conductive bonding layer disposed on the plurality of second pad electrodes, and a flexible film electrically connected to the plurality of second pad electrodes through the conductive bonding layer.

The plurality of first pad electrodes may be disposed on the same layer and made of the same material as a source electrode and a drain electrode of each of the plurality of transistors.

The display device may further include a plurality of metal layers disposed between the plurality of first pad electrodes and the substrate and connected to the plurality of first pad electrodes. The plurality of metal layers may include a first metal layer, and a second metal layer disposed on the first metal layer.

The display device may further include a plurality of capacitors disposed in the plurality of subpixels. The first metal layer may be made of the same material as a gate electrode of each of the plurality of transistors. The second metal layer may be made of the same material as one capacitor electrode of the plurality of capacitors.

The display device may further include a plurality of link lines connected to the plurality of first pad electrodes extending to the display area. The plurality of link lines may be made of the same material as the first metal layer and the second metal layer.

Although the embodiments of the present disclosure have been described in detail with reference to the accompanying drawings, the present disclosure is not limited thereto and may be embodied in many different forms without departing from the technical concept of the present disclosure. Therefore, the embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present disclosure. All the technical concepts in the equivalent scope of the present disclosure should be construed as falling within the scope of the present disclosure.

What is claimed is:

1. A display device, comprising:
a substrate comprising a display area with a plurality of subpixels, and a non-display area surrounding the display area;
a plurality of transistors in the plurality of subpixels;
a planarization layer covering the plurality of transistors;
a light-emitting element on the planarization layer;
a plurality of first pad electrodes in the non-display area; and
an organic film on the plurality of first pad electrodes,
wherein the planarization layer covers edges of the plurality of first pad electrodes and is spaced apart from the organic film.

2. The display device of claim 1, wherein the organic film comprises a plurality of organic patterns spaced apart from each other.

3. The display device of claim 1, wherein the organic film includes a same material as the planarization layer.

4. The display device of claim 3, further comprising:
a plurality of second pad electrodes on the plurality of first pad electrodes and the organic film, the plurality of second pad electrodes configured to adjoin the plurality of first pad electrodes.

5. The display device of claim 4, further comprising:
a touch detection part on the light-emitting element in the display area,
wherein the touch detection part comprises an insulation layer, a plurality of touch electrodes, and a plurality of touch bridge electrodes, and
wherein the plurality of second pad electrodes include a same material as one of the plurality of touch electrodes and the plurality of touch bridge electrodes.

6. The display device of claim 5, wherein the insulation layer is on the plurality of first pad electrodes and covers the organic film, and
wherein the plurality of second pad electrodes is connected to the plurality of first pad electrodes through a contact hole of the insulation layer.

7. The display device of claim 4, further comprising:
a conductive bonding layer on the plurality of second pad electrodes; and
a flexible film electrically connected to the plurality of second pad electrodes through the conductive bonding layer.

8. The display device of claim 1, wherein the plurality of first pad electrodes is on a same layer and includes a same material as a source electrode and a drain electrode of each of the plurality of transistors.

9. The display device of claim 1, further comprising:
a plurality of metal layers between the plurality of first pad electrodes and the substrate, the plurality of metal layers connected to the plurality of first pad electrodes,
wherein the plurality of metal layers comprise:
a first metal layer; and
a second metal layer on the first metal layer.

10. The display device of claim 9, further comprising:
a plurality of capacitors in the plurality of subpixels,
wherein the first metal layer includes a same material as a gate electrode of each of the plurality of transistors, and
wherein the second metal layer includes a same material as one capacitor electrode of the plurality of capacitors.

11. The display device of claim 9, further comprising:
a plurality of link lines connected to the plurality of first pad electrodes, the plurality of link lines extending to the display area,
wherein the plurality of link lines include a same material as the first metal layer and the second metal layer.

12. A display device, comprising:
a substrate comprising a display area with a plurality of subpixels, and a non-display area surrounding the display area;
a first pad electrode in the non-display area;
a planarization layer on the first pad electrode, the planarization layer covering an edge portion of the first pad electrode; and
an organic film on a portion of the first pad electrode, the portion of the first pad electrode not being covered by the planarization layer,
wherein the planarization layer is spaced apart from the organic film so that the portion of the first pad electrode is exposed.

13. The display device of claim 12, wherein the organic film comprises a plurality of organic patterns spaced apart from each other.

14. The display device of claim 12, wherein the organic film comprises a plurality of organic patterns spaced apart from each other.

15. The display device of claim 12, wherein the organic film includes a same material as the planarization layer.

16. The display device of claim 12, further comprising:
a second pad electrode on the organic film and the portion of the first pad electrode that is exposed.
